(19) United States
(12) Patent Application Publication
(10) Pub. No.: US 2025/0358968 A1
(43) Pub. Date: Nov. 20, 2025

(54) WIRELESS COMMUNICATION DEVICES WITH ALIGNMENT FEATURES AND RELATED METHODS

(71) Applicant: PLUME DESIGN, INC., Palo Alto, CA (US)

(72) Inventors: Ming-Tsung SU, Taipei City (TW); Nora YAN, Taipei City (TW); Richard CHANG, Los Altos Hills, CA (US); Jeffrey ChiFai LIEW, Millbrae, CA (US); Miroslav SAMARDZIJA, Mountain View, CA (US); Liem Hieu Dinh VO, San Jose, CA (US)

(21) Appl. No.: 18/663,489

(22) Filed: May 14, 2024

(51) Int. Cl. H05K 7/20; H05K 1/02

(52) U.S. Cl. CPC H05K 7/2039; H05K 1/0203; H05K 2201/066

(57) ABSTRACT

A wireless communication device may include a first heat spreader including at least two main locating pins extending axially away from an inward-facing surface of the first heat spreader, a printed circuit board (PCB) adjacent to the first heat spreader, a second heat spreader adjacent to the PCB, a power board adjacent to the second heat spreader, and a third heat spreader adjacent to the power board. The third heat spreader may be secured to the at least two main locating pins to assemble the first heat spreader, PCB, second heat spreader, power board, and third heat spreader together. Various other devices and methods are related to such wireless communication devices.

### BRIEF DESCRIPTION OF THE DRAWINGS

FIG. 1 is an exploded view of heat spreader and printed circuit board (PCB) components that form a main body of a wireless communication device, according to at least one embodiment of the present disclosure.

FIG. 2 is a cross-sectional perspective view of the main body of the wireless communication device after assembly, according to at least one embodiment of the present disclosure.

FIG. 3 is an exploded view illustrating lighting components to be assembled with the main body, according to at least one embodiment of the present disclosure.

FIG. 4 is an exploded view illustrating a speaker grill component to be assembled with main body, according to at least one embodiment of the present disclosure.

FIG. 5 is an exploded view illustrating a first end cover to be assembled with the main body, according to at least one embodiment of the present disclosure.

FIG. 6 is an exploded view illustrating an antenna carrier to be assembled with the main body, according to at least one embodiment of the present disclosure.

FIG. 7A is a perspective view of an outer enclosure and FIG. 7B is a perspective view of a portion of the main body of the wireless communication device, according to at least one embodiment of the present disclosure.

FIG. 8A is an exploded view illustrating a second end cover to be assembled to the main body and FIG. 8B is a cross-sectional perspective view of the wireless communication device illustrating the second end cover assembled to the main body, according to at least one embodiment of the present disclosure.

FIG. 9 is a flow chart illustrating a method of forming a wireless communication device, according to at least one embodiment of the present disclosure.

Throughout the drawings, identical reference characters and descriptions indicate similar, but not necessarily identical, elements. While the example embodiments described herein are susceptible to various modifications and alternative forms, specific embodiments have been shown by way of example in the drawings and will be described in detail herein. However, the example embodiments described herein are not intended to be limited to the particular forms disclosed. Rather, the present disclosure covers all modifications, equivalents, and alternatives falling within the scope of the appended claims.

### DETAILED DESCRIPTION OF EXAMPLE EMBODIMENTS

Wireless communication devices, including wireless extenders and wireless routers, play an important role in modern digital communication. These devices enable data transmission over distance without requiring physical connections or wires. A wireless router, included in most wireless networks, broadcasts a wireless signal to an area to connect other devices that have wireless receivers to the internet or to a local network. A wireless extender, also known as a Wi-Fi range extender, enhances and expands the coverage area of a wireless internet connection by boosting an existing Wi-Fi signal.

Features from any of the embodiments described herein may be used in combination with one another in accordance with the general principles described herein. These and other embodiments, features, and advantages will be more fully understood upon reading the following detailed description in conjunction with the accompanying drawings and claims.

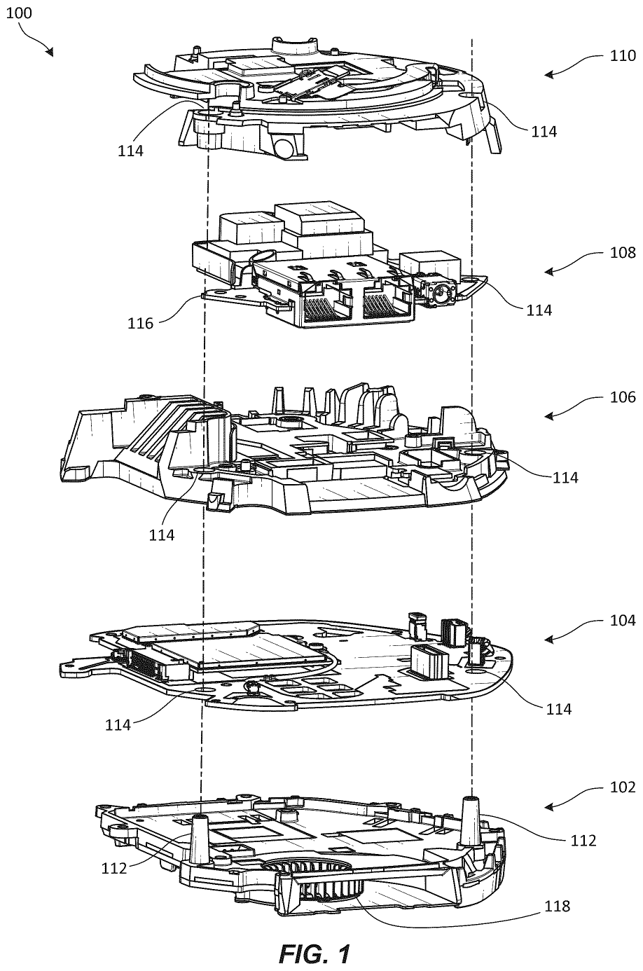

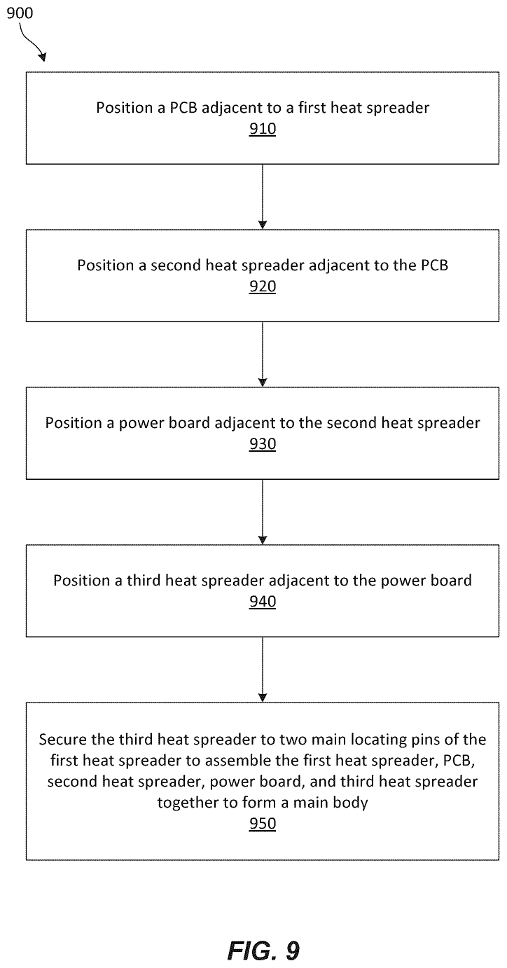

The following will provide, with reference to FIGS. 1-8, detailed descriptions of a wireless communication device and an example assembly process thereof. Then, with reference to FIG. 9, an example method of forming a wireless communication device will be described.

FIG. 1 is an exploded view of heat spreader and printed circuit board (PCB) components that form a main body 100 of a wireless communication device (e.g., a wireless signal extender, a wireless router, etc.), according to at least one embodiment of the present disclosure. For example, the main body 100 may include a first heat spreader 102, a PCB 104 axially adjacent to the first heat spreader 102, a second heat spreader 106 axially adjacent to the PCB 104 on an opposite side of the PCB 104 from the first heat spreader 102, a power board 108 axially adjacent to the second heat spreader 106 on an opposite side of the second heat spreader 106 from the PCB, and a third heat spreader 110 axially adjacent to the power board 108 on an opposite side of the power board 108 from the second heat spreader 106.

For convenience and clarity, as used herein the term “axially” may refer to a direction in which these components of the main body 100 are stacked over each other (e.g., up and down from the perspective of FIG. 1). Similarly, the term “radially” may refer to a direction perpendicular to the axial direction. The terms “inward” and “outward” may refer to, respectively, axially toward a center of the main body 100 and axially away from the center of the main body 100 (e.g., respectively toward and away from the second heat spreader 106).

To facilitate assembly and alignment of the components of the main body 100, the first heat spreader 102 may include at least two main locating pins 112 extending axially away from an inward-facing surface of the first heat spreader 102. The other components of the main body 100 may include one or more features complementary to the main locating pins 112, such as through holes 114 and/or grooves 116. During assembly, these through holes 114 and/or grooves 116 may be aligned and engaged with the main locating pins 112 to properly align and orient the other components with the first heat spreader 102 and with each other.

The PCB 104 may support and/or house various functional features of the wireless communication device, such as one or more processors, wireless transceivers, amplifiers, data connectors, memory, controllers, etc. The power board 108 may support and/or house various power-related features, such as a one or more capacitors, transformers, diodes, input connectors, output connectors, transistors, filters, rectifiers, resistors, inductors, control integrated circuits, fuses, switches, sensors, drivers, etc.

The components of the PCB 104 and of the power board 108 may generate heat during operation. The first, second, and third heat spreaders 102, 106, 110 may be configured to dissipate the heat generated by the PCB 104 and power board 108. For example, the first, second, and third heat spreaders 102, 106, 110 may be formed of a thermally conductive material, such as a metallic material. These materials may be in thermal contact with (e.g., abut against) portions of the PCB 104 and/or power board 108 to receive the heat via thermal conduction. In addition, the geometry of the first, second, and third heat spreaders 102, 106, 110 may be designed to dissipate the heat, such as by including fins, holes, posts, etc. A cooling fan 118 may be configured to force air across the first, second, and/or third heat spreaders 102, 106, 110 to further dissipate the heat generated by the PCB 104 and power board 108 during operation.

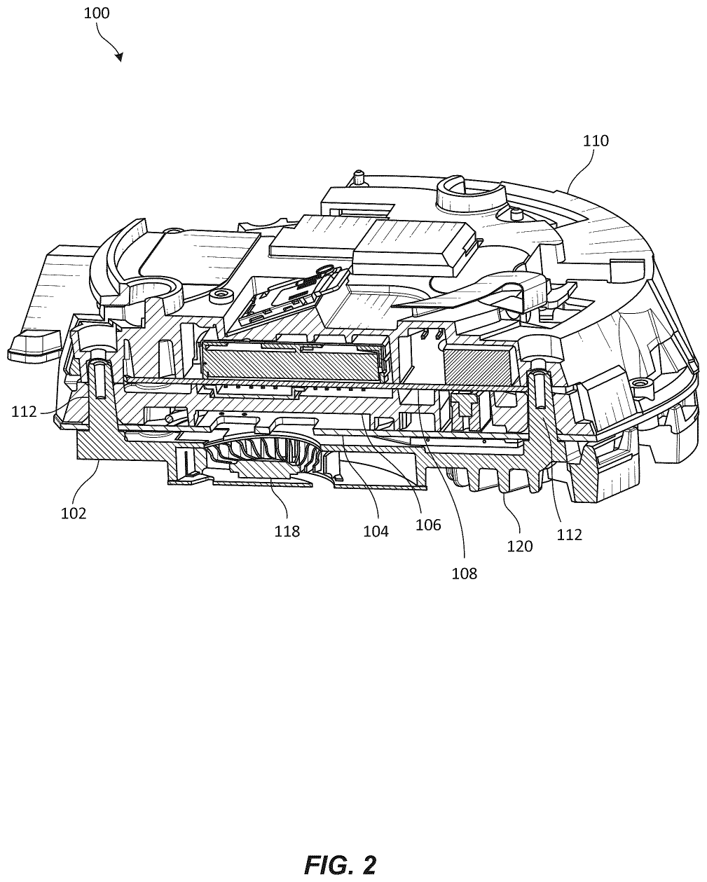

FIG. 2 is a cross-sectional perspective view of the main body 100 of the wireless communication device after assembly, according to at least one embodiment of the present disclosure. As can be seen in FIG. 2, the main locating pins 112 of the first heat spreader 102 may pass through holes 114 and/or along grooves 116 (holes 114 and grooves 116 labeled in FIG. 1) of the PCB 104, second heat spreader 106, power board 108, and third heat spreader 110 to engage and align with these other components of the main body 100.

The main locating pins 112 may include respective recesses therein for securing, such as with respective fasteners (e.g., screws, bolts, pins, etc.), the first heat spreader 102 to the third heat spreader 110, with the PCB 104, second heat spreader 106, and power board 108 sandwiched between the first heat spreader 102 and third heat spreader 110.

In some embodiments, the main locating pins 112 may be an integral, unitary part of a metallic base portion of the first heat spreader 102.

Although two main locating pins 112 are shown in FIGS. 1 and 2, the present disclosure is not so limited. In additional embodiments, three or more main locating pins 112 may be present to align the components of the main body 100 with each other. In addition, the two or more main locating pins 112 may extend from (e.g., may be a part of) components other than the first heat spreader 102. By way of example and not limitation, in additional embodiments the main locating pins 112 may extend from the third heat spreader 110 instead of from the first heat spreader 102. In further embodiments, one locating pin 112 may extend from the first heat spreader 102 toward the third heat spreader 110 and one locating pin 112 may extend from the third heat spreader 110 toward the first heat spreader 102.

As illustrated in FIG. 2, the first heat spreader 102, second heat spreader 106, and/or third heat spreader 110 may include fins 120 to facilitate heat dissipation.

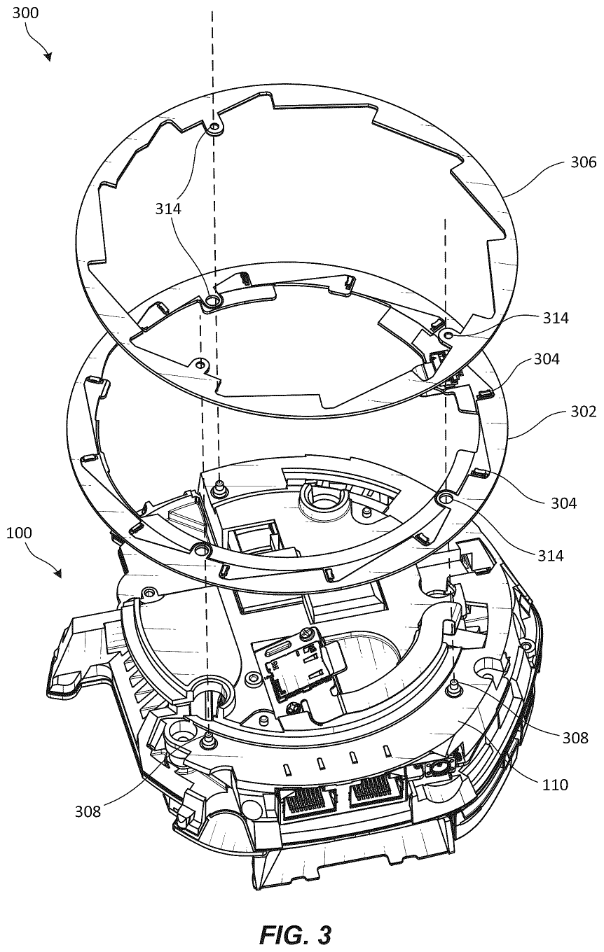

FIG. 3 is an exploded view illustrating lighting components 300 to be assembled with the main body 100, according to at least one embodiment of the present disclosure. The lighting components 300 may include a lighting PCB 302, which may include light-emitting diodes (LEDs) 304 mounted thereon, and a light guide 306. The light guide 306 may be or include a translucent (e.g., transparent or partially transparent) material shaped and sized to cover the LEDs 304. When assembled, the lighting components 300 may be axially adjacent to the third heat spreader 110 on an opposite side of the third heat spreader 110 from the power board 108.

The third heat spreader 110 of the main body 100 may include two or more lighting alignment pins 308 extending away from an outward-facing surface of the third heat spreader 110. The lighting components 300 may be aligned with the third heat spreader 110 via the lighting alignment pins 308. For example, the lighting components may include holes 314 and/or grooves that are positioned and shaped to receive and/or engage with the lighting alignment pins 308, as illustrated by dashed lines in FIG. 3.

As illustrated in FIG. 3, the lighting components 300 may generally have a ring shape.

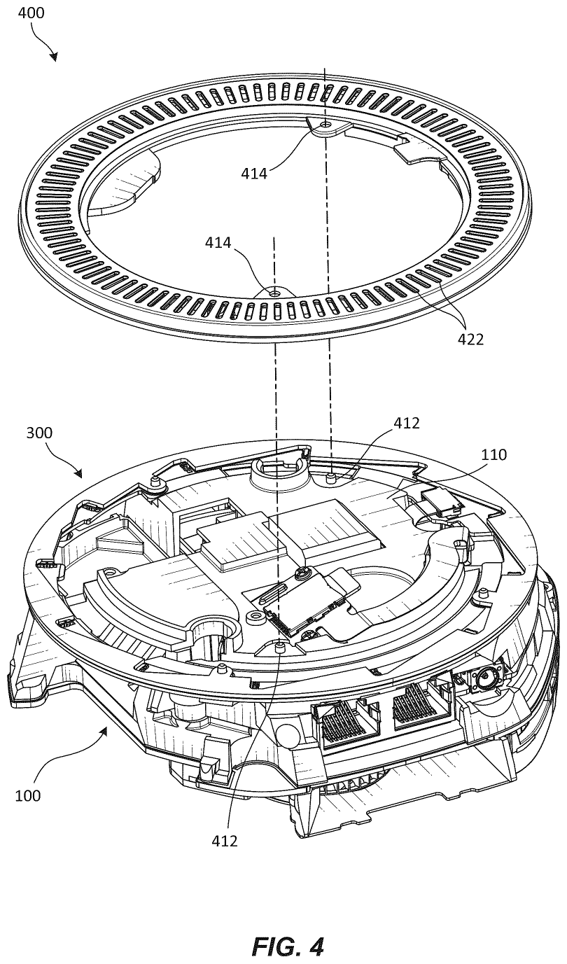

FIG. 4 is an exploded view illustrating a speaker grill component 400 to be assembled with main body 100, according to at least one embodiment of the present disclosure. The speaker grill component 400 may be positioned axially adjacent to the third heat spreader 110 on an opposite side of the third heat spreader 110 from the power board 108.

The third heat spreader 110 may include two or more speaker grill alignment pins 412 extending away from the outward-facing surface of the third heat spreader 110. The speaker grill component 400 may be aligned with the third heat spreader 110 via the two or more speaker grill alignment pins 412. For example, the speaker grill component 400 may include two or more respective holes 414 and/or grooves that are positioned and shaped to receive and/or engage with the speaker grill alignment pins 412, as illustrated by dashed lines in FIG. 4.

As illustrated in FIG. 4, the speaker grill component 400 may generally have a ring shape. Speaker apertures 422 may pass through the speaker grill component and may be arranged radially around the speaker grill component 400. In addition to providing passageways to facilitate sound escaping the wireless communication device, the speaker apertures 422 may also improve cooling by allowing air to flow through the wireless communication device and out of or into the speaker apertures 422.

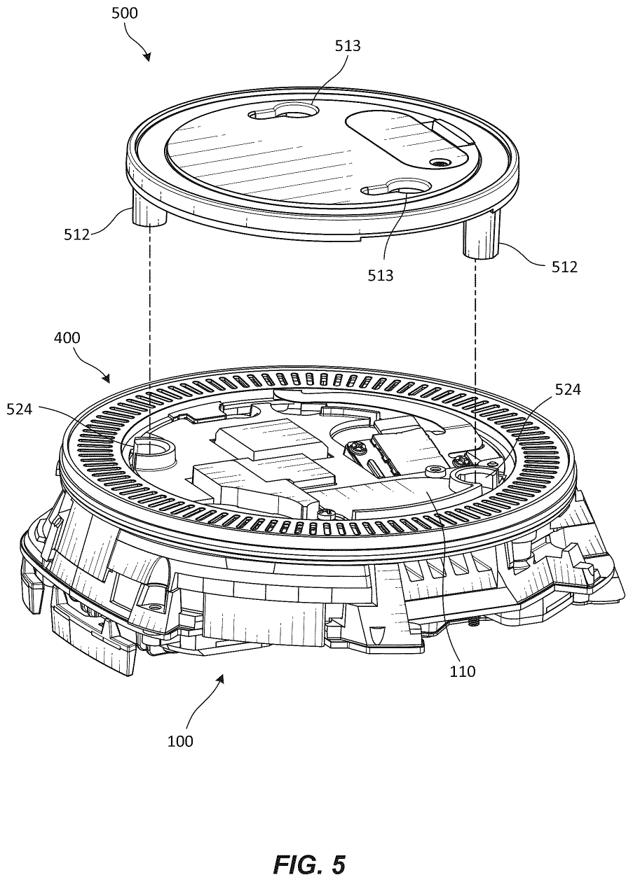

FIG. 5 is an exploded view illustrating a first end cover 500 to be assembled with the main body 100, according to at least one embodiment of the present disclosure. The first end cover 500 may be positioned axially adjacent to the third heat spreader 110 on an opposite side of the third heat spreader 110 from the power board 108.

The first end cover 500 may include at least two first end cover alignment pins 512 extending inward from the first end cover 500. The first end cover 500 may be aligned with the third heat spreader 110 via the first end cover alignment pins 512. For example, the third heat spreader 110 may include receptacles 524 positioned and shaped to receive and/or engage with the first end cover alignment pins 512.

In some examples, the first end cover 500 may include mounting holes 513 (e.g., keyhole slots) for mounting the wireless communication device on a wall or other vertical surface, such as with pegs, nails, screws, etc. The wireless communication device may also be capable of being mounted or positioned on a horizontal support surface, such as a tabletop, floor, ceiling, etc.

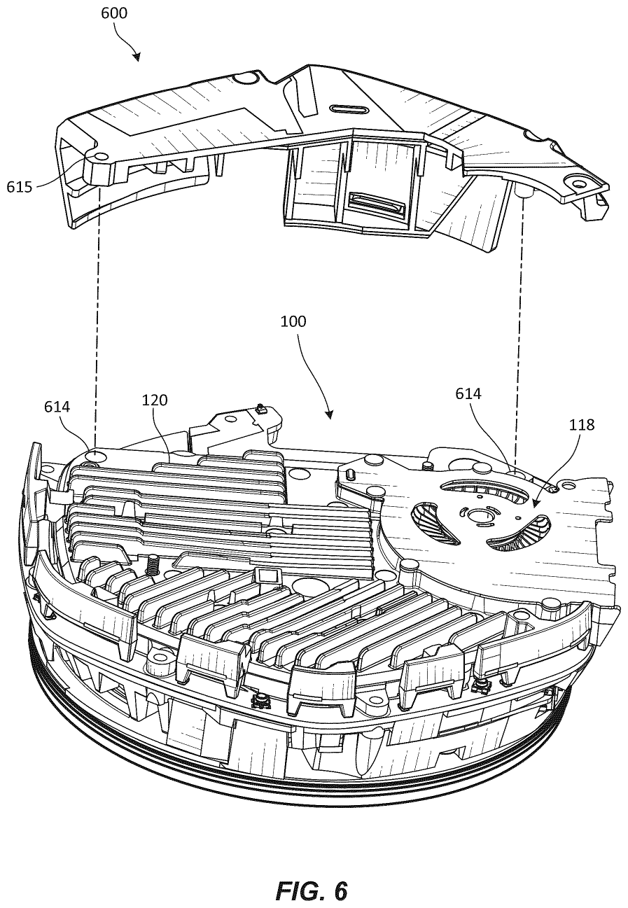

FIG. 6 is an exploded view illustrating an antenna carrier 600 to be assembled with the main body 100, according to at least one embodiment of the present disclosure. In FIG. 6, the main body 100 is illustrated in a flipped orientation compared to the views of FIGS. 1-5. When assembled, the antenna carrier 600 may be positioned radially adjacent to the first heat spreader 102.

The antenna carrier 600 may include at least one antenna carrier locating pin 612 extending from a surface of the antenna carrier 600. The antenna carrier 600 may be aligned with the first heat spreader 110 via the at least one antenna carrier locating pin 612. For example, the first heat spreader may include at least one corresponding hole 614 that is positioned and shaped to receive and/or engage with the at least one antenna carrier locating pin 612. In the example shown in FIG. 6, the first heat spreader 110 may include an additional hole 614 and the antenna carrier 600 may include an alignment hole 615. A fastener (e.g., a screw, bolt, pin, etc.) may pass through the alignment hole 615 and into the additional hole 614 in the first heat spreader 110 to align and secure the antenna carrier 600 to the first heat spreader 110.

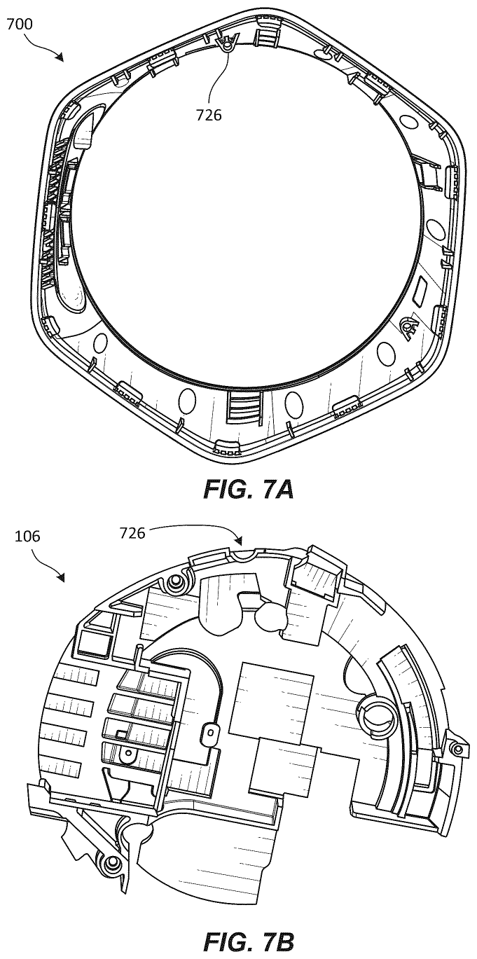

FIG. 7A is a perspective view of an outer enclosure 700 and FIG. 7B is a perspective view of the second heat spreader 106 of the wireless communication device, according to at least one embodiment of the present disclosure. The outer enclosure 700 of FIG. 7A is to be assembled to (e.g., laterally surrounding) the main body 100.

The outer enclosure 700 may include one or more alignment features that are complementary to one or more corresponding features of the main body 100. For example, the outer enclosure 700 may include a screw boss 726 that extends radially inward. The second heat spreader 106 may include at least one corresponding groove 728 for receiving and engaging with the screw boss 726 when the outer enclosure 700 is assembled to the main body 100.

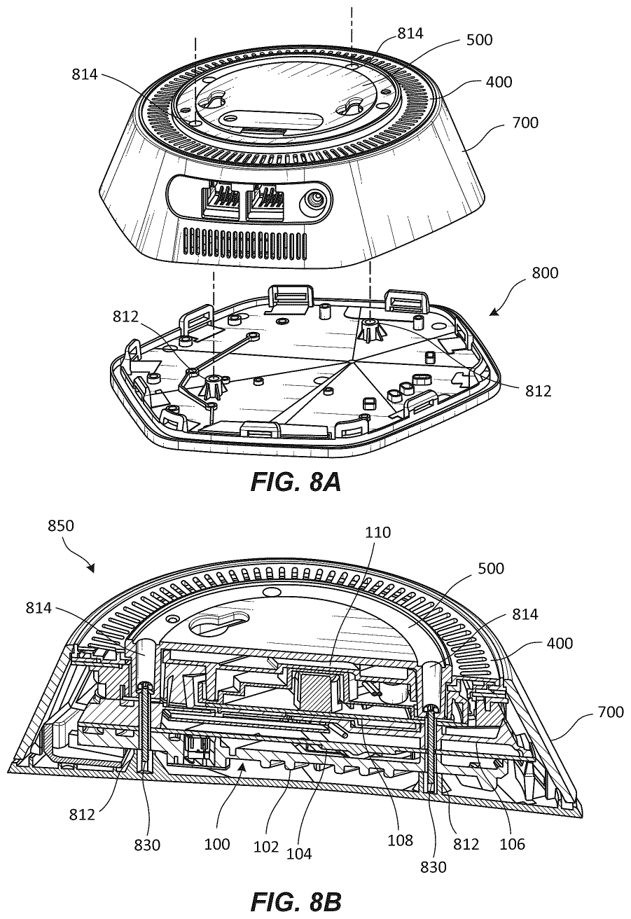

FIG. 8A is an exploded view illustrating a second end cover 800 to be assembled to the main body 100 and FIG. 8B is a cross-sectional perspective view of the wireless communication device 850 illustrating the second end cover 800 assembled to the main body 100, according to at least one embodiment of the present disclosure. The second end cover 800 may be positioned axially adjacent to the first heat spreader 102 on an opposite side of the first heat spreader 102 from the PCB 104.

The second end cover 800 may include screw bosses 812 extending from an inward-facing surface of the second end cover 800. The second end cover 800 may be aligned with the other components of the wireless communication device via the screw bosses 812. As shown in FIG. 8B, the main body 100 may be sandwiched between the first end cover 500 and the second end cover 800. Alignment holes 814 in the first end cover 500 may be aligned with the screw bosses 812 of the second end cover 800. Fasteners 830 (e.g., screws) may be passed through the alignment holes 814 and engaged with the screw bosses 812 to secure the first end cover 500 to the second end cover 800.

FIG. 9 is a flow chart illustrating a method 900 of forming a wireless communication device, according to at least one embodiment of the present disclosure.

At operation 910, a PCB may be positioned adjacent to a first heat spreader. The first head spreader may include at least two main locating pins that extend away from a surface of the first heat spreader (e.g., an inward-facing surface, as explained above).

At operation 920, a second heat spreader may be positioned adjacent to the PCB and on an opposite side of the PCB from the first heat spreader.

At operation 930, a power board may be positioned adjacent to the second heat spreader and on an opposite side of the second heat spreader from the PCB.

At operation 940, a third heat spreader may be positioned adjacent to the power board and on an opposite side of the power board from the second heat spreader.

At operation 950, the third heat spreader may be secured to the at least two main locating pins of the first heat spreader to assemble the first heat spreader, PCB, second heat spreader, power board, and third heat spreader together to form a main body (e.g., a functional assembly) of the wireless communication device.

In additional examples, a first end cover may be positioned adjacent to the third heat spreader of the main body and a second end cover may be positioned adjacent to the first heat spreader of the main body. The first end cover may be secured to the second end cover, such as with at least one fastener. The main body may be sandwiched and secured between the first end cover and the second end cover. In some embodiments, prior to securing the first end cover to the second end cover, an outer enclosure may be positioned to laterally surround the main body.

Accordingly, the present disclosure includes wireless communication devices (e.g., wireless extenders, wireless routers, etc.) that are compact and easy to assemble. For example, alignment features may be used to facilitate alignment and assembly of the various components of the wireless communication devices.

In some examples, relational terms, such as “first,” “second,” etc., may be used for clarity and convenience in understanding the disclosure and accompanying drawings and do not connote or depend on any specific preference, orientation, or order, except where the context clearly indicates otherwise.

The following example embodiments are also included in the present disclosure.
Example 1. A wireless communication device, including: a first heat spreader including at least two main locating pins extending axially away from an inward-facing surface of the first heat spreader; a printed circuit board (PCB) axially adjacent to the first heat spreader; a second heat spreader axially adjacent to the PCB on an opposite side of the PCB from the first heat spreader; a power board axially adjacent to the second heat spreader on an opposite side of the second heat spreader from the PCB; and a third heat spreader axially adjacent to the power board on an opposite side of the power board from the second heat spreader, wherein the third heat spreader is secured to the at least two main locating pins to assemble the first heat spreader, PCB, second heat spreader, power board, and third heat spreader together.
Example 2. The wireless communication device of Example 1, further including at least two fasteners, wherein the at least two locating pins include respective recesses therein and the at least two fasteners engage with the respective recesses to secure the third heat spreader to the first heat spreader.
Example 3. The wireless communication device of Example 2, wherein the at least two fasteners include at least two screws.
Example 4. The wireless communication device of any of Examples 1 through 3, wherein the PCB includes at least two PCB through holes and the at least two locating pins of the first heat spreader respectively pass through the at least two PCB through holes.
Example 5. The wireless communication device of any of Examples 1 through 4, wherein the second heat spreader includes at least two heat spreader through holes and the at least two locating pins of the first heat spreader respectively pass through the at least two heat spreader through holes.
Example 6. The wireless communication device of any of Examples 1 through 5, wherein the power board includes at least two power board through holes and the at least two locating pins of the first heat spreader respectively pass through the at least two power board through holes.
Example 7. The wireless communication device of any of Examples 1 through 6, wherein the PCB includes a wireless transceiver.
Example 8. The wireless communication device of any of Examples 1 through 7, wherein the at least two locating pins are an integral, unitary part of a metallic base portion of the first heat spreader.
Example 9. The wireless communication device of any of Examples 1 through 8, further including lighting components axially adjacent to the third heat spreader on an opposite side of the third heat spreader from the power board, wherein the third heat spreader includes at least two lighting alignment pins extending away from an outward-facing surface of the third heat spreader and the lighting components are aligned with the third heat spreader via the at least two lighting alignment pins.
Example 10. The wireless communication device of any of Examples 1 through 9, further including a speaker grill component axially adjacent to the third heat spreader on an opposite side of the third heat spreader from the power board, wherein the third heat spreader includes at least two speaker grill alignment pins extending away from an outward-facing surface of the third heat spreader and the speaker grill component is aligned with the third heat spreader via the at least two speaker grill alignment pins.
Example 11. The wireless communication device of any of Examples 1 through 10, further including a first end cover axially adjacent to the third heat spreader on an opposite side of the third heat spreader from the power board, wherein the first end cover includes at least two first end cover alignment pins extending inward from the first end cover and the first end cover is aligned with the third heat spreader via the at least two first end cover alignment pins.
Example 12. The wireless communication device of any of Examples 1 through 11, further including an antenna carrier radially adjacent to the first heat spreader, wherein the antenna carrier includes at least one antenna carrier locating pin extending from a surface of the antenna carrier and the antenna carrier is aligned with the first heat spreader via the at least one antenna carrier locating pin.
Example 13. The wireless communication device of any of Examples 1 through 12, further including an outer enclosure radially surrounding the first heat spreader, PCB, second heat spreader, power board, and third heat spreader, wherein the outer enclosure includes at least one enclosure alignment extension protruding radially inward from an inner surface of the outer enclosure and the outer enclosure is aligned with the first heat spreader, PCB, second heat spreader, power board, and third heat spreader via the at least one enclosure alignment extension.
Example 14. The wireless communication device of any of Examples 1 through 13, further including a second end cover axially adjacent to the first heat spreader on an opposite side of the first heat spreader from the PCB, wherein the second end cover includes at least two screw bosses extending from an inward surface of the second end cover and the second end cover is aligned with the first heat spreader via the at least two screw bosses.
Example 15. A wireless communication device, including: a first end cover configured to mount the wireless communication device to a wall; a functional assembly adjacent to the first end cover, the functional assembly including: a first heat spreader including at least two main locating pins extending from a surface of the first heat spreader toward the first end cover; a printed circuit board (PCB) adjacent to the first heat spreader and between the first heat spreader and the first end cover; a second heat spreader adjacent to the PCB and between the PCB and the first end cover; a power board adjacent to the second heat spreader and between the second heat spreader and the first end cover; and a third heat spreader adjacent to the power board and between the power board and the first end cover, wherein the third heat spreader is secured to the at least two main locating pins to assemble the first heat spreader, PCB, second heat spreader, power board, and third heat spreader together; and a second end cover on a side of the functional assembly opposite from the first end cover, wherein the second end cover is secured to the first end cover with at least one fastener and the functional assembly is positioned between the first end cover and the second end cover.
Example 16. The wireless communication device of Example 15, further including an outer enclosure laterally surrounding the functional assembly and extending between the first end cover and the second end cover.
Example 17. The wireless communication device of Example 15 or Example 16, further including an antenna carrier operably coupled to a wireless transceiver of the PCB, wherein the antenna carrier is mechanically secured to the first heat spreader.
Example 18. A method of forming a wireless communication device, the method including: positioning a printed circuit board (PCB) adjacent to a first heat spreader that includes at least two main locating pins extending away from a surface of the first heat spreader; positioning a second heat spreader adjacent to the PCB on an opposite side of the PCB from the first heat spreader; positioning a power board adjacent to the second heat spreader on an opposite side of the second heat spreader from the PCB; positioning a third heat spreader adjacent to the power board on an opposite side of the power board from the second heat spreader; and securing the third heat spreader to the at least two main locating pins to assemble the first heat spreader, PCB, second heat spreader, power board, and third heat spreader together to form a main body.
Example 19. The method of Example 18, further including: positioning a first end cover adjacent to the third heat spreader of the main body; positioning a second end cover adjacent to the first heat spreader of the main body; and securing the first end cover to the second end cover with at least one fastener.
Example 20. The method of Example 19, further including: prior to securing the first end cover to the second end cover, positioning an outer enclosure to laterally surround the main body.

While the foregoing disclosure sets forth various embodiments using specific block diagrams, flowcharts, and examples, each block diagram component, flowchart step, operation, and/or component described and/or illustrated herein may be implemented, individually and/or collectively, using a wide range of hardware, software, or firmware (or any combination thereof) configurations. In addition, any disclosure of components contained within other components should be considered example in nature since many other architectures can be implemented to achieve the same functionality.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various example methods described and/or illustrated herein may also omit one or more of the steps described or illustrated herein or include additional steps in addition to those disclosed.

The preceding description has been provided to enable others skilled in the art to best utilize various aspects of the example embodiments disclosed herein. This example description is not intended to be exhaustive or to be limited to any precise form disclosed. Many modifications and variations are possible without departing from the spirit and scope of the instant disclosure. The embodiments disclosed herein should be considered in all respects illustrative and not restrictive. Reference should be made to the appended claims and their equivalents in determining the scope of the instant disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A wireless communication device, comprising:
a first heat spreader including at least two main locating pins extending axially away from an inward-facing surface of the first heat spreader;
a printed circuit board (PCB) axially adjacent to the first heat spreader;
a second heat spreader axially adjacent to the PCB on an opposite side of the PCB from the first heat spreader;
a power board axially adjacent to the second heat spreader on an opposite side of the second heat spreader from the PCB; and
a third heat spreader axially adjacent to the power board on an opposite side of the power board from the second heat spreader,
wherein the third heat spreader is secured to the at least two main locating pins to assemble the first heat spreader, PCB, second heat spreader, power board, and third heat spreader together.

2. The wireless communication device of claim 1, further comprising at least two fasteners, wherein the at least two locating pins comprise respective recesses therein and the at least two fasteners engage with the respective recesses to secure the third heat spreader to the first heat spreader.

3. The wireless communication device of claim 2, wherein the at least two fasteners comprise at least two screws.

4. The wireless communication device of claim 1, wherein the PCB comprises at least two PCB through holes and the at least two locating pins of the first heat spreader respectively pass through the at least two PCB through holes.

5. The wireless communication device of claim 1, wherein the second heat spreader comprises at least two heat spreader through holes and the at least two locating pins of the first heat spreader respectively pass through the at least two heat spreader through holes.

6. The wireless communication device of claim 1, wherein the power board comprises at least two power board through holes and the at least two locating pins of the first heat spreader respectively pass through the at least two power board through holes.

7. The wireless communication device of claim 1, wherein the PCB comprises a wireless transceiver.

8. The wireless communication device of claim 1, wherein the at least two locating pins are an integral, unitary part of a metallic base portion of the first heat spreader.

9. The wireless communication device of claim 1, further comprising lighting components axially adjacent to the third heat spreader on an opposite side of the third heat spreader from the power board,
wherein the third heat spreader comprises at least two lighting alignment pins extending away from an outward-facing surface of the third heat spreader and the lighting components are aligned with the third heat spreader via the at least two lighting alignment pins.

10. The wireless communication device of claim 1, further comprising a speaker grill component axially adjacent to the third heat spreader on an opposite side of the third heat spreader from the power board,
wherein the third heat spreader comprises at least two speaker grill alignment pins extending away from an outward-facing surface of the third heat spreader and the speaker grill component is aligned with the third heat spreader via the at least two speaker grill alignment pins.

11. The wireless communication device of claim 1, further comprising a first end cover axially adjacent to the third heat spreader on an opposite side of the third heat spreader from the power board,
wherein the first end cover comprises at least two first end cover alignment pins extending inward from the first end cover and the first end cover is aligned with the third heat spreader via the at least two first end cover alignment pins.

12. The wireless communication device of claim 1, further comprising an antenna carrier radially adjacent to the first heat spreader,
wherein the antenna carrier comprises at least one antenna carrier locating pin extending from a surface of the antenna carrier and the antenna carrier is aligned with the first heat spreader via the at least one antenna carrier locating pin.

13. The wireless communication device of claim 1, further comprising an outer enclosure radially surrounding the first heat spreader, PCB, second heat spreader, power board, and third heat spreader,
wherein the outer enclosure comprises at least one enclosure alignment extension protruding radially inward from an inner surface of the outer enclosure and the outer enclosure is aligned with the first heat spreader, PCB, second heat spreader, power board, and third heat spreader via the at least one enclosure alignment extension.

14. The wireless communication device of claim 1, further comprising a second end cover axially adjacent to the first heat spreader on an opposite side of the first heat spreader from the PCB,
wherein the second end cover comprises at least two screw bosses extending from an inward surface of the second end cover and the second end cover is aligned with the first heat spreader via the at least two screw bosses.

15. A wireless communication device, comprising:
a first end cover configured to mount the wireless communication device to a wall;
a functional assembly adjacent to the first end cover, the functional assembly comprising:
a first heat spreader including at least two main locating pins extending from a surface of the first heat spreader toward the first end cover;
a printed circuit board (PCB) adjacent to the first heat spreader and between the first heat spreader and the first end cover;
a second heat spreader adjacent to the PCB and between the PCB and the first end cover;
a power board adjacent to the second heat spreader and between the second heat spreader and the first end cover; and
a third heat spreader adjacent to the power board and between the power board and the first end cover, wherein the third heat spreader is secured to the at least two main locating pins to assemble the first heat spreader, PCB, second heat spreader, power board, and third heat spreader together; and
a second end cover on a side of the functional assembly opposite from the first end cover, wherein the second end cover is secured to the first end cover with at least one fastener and the functional assembly is positioned between the first end cover and the second end cover.

16. The wireless communication device of claim 15, further comprising an outer enclosure laterally surrounding the functional assembly and extending between the first end cover and the second end cover.

17. The wireless communication device of claim 15, further comprising an antenna carrier operably coupled to a wireless transceiver of the PCB, wherein the antenna carrier is mechanically secured to the first heat spreader.

18. A method of forming a wireless communication device, the method comprising:
positioning a printed circuit board (PCB) adjacent to a first heat spreader that includes at least two main locating pins extending away from a surface of the first heat spreader;
positioning a second heat spreader adjacent to the PCB on an opposite side of the PCB from the first heat spreader;
positioning a power board adjacent to the second heat spreader on an opposite side of the second heat spreader from the PCB;
positioning a third heat spreader adjacent to the power board on an opposite side of the power board from the second heat spreader; and
securing the third heat spreader to the at least two main locating pins to assemble the first heat spreader, PCB, second heat spreader, power board, and third heat spreader together to form a main body.

19. The method of claim 18, further comprising:
positioning a first end cover adjacent to the third heat spreader of the main body;
positioning a second end cover adjacent to the first heat spreader of the main body; and
securing the first end cover to the second end cover with at least one fastener.

20. The method of claim 19, further comprising:
prior to securing the first end cover to the second end cover, positioning an outer enclosure to laterally surround the main body.
